(19) United States
(12) Patent Application Publication
(10) Pub. No.: US 2002/0096113 A1
(43) Pub. Date: Jul. 25, 2002

(54) Apparatus and method for the removal of backflow vapors

(76) Inventor: Tue Nguyen, Fremont, CA (US)

Correspondence Address: Tue Nguyen, 496 Olive Ave., Fremont, CA, 94539, US

(21) Appl. No.: 09/765,904

(22) Filed: Jan. 19, 2001

(51) Int. Cl. C23C 16/00

(52) U.S. Cl. 118/715; 118/719; 55/385.1

(57) ABSTRACT

An apparatus for semiconductor processing includes a process chamber having a process evacuation pathway from the process volume to atmosphere; a transfer module to transfer a workpiece to and from the process chamber, the transfer module and process chamber in combination defining a backflow pathway; and a backflow remover element coupled to the backflow pathway, the backflow remover element removing a portion of process vapor in the backflow pathway.

### FIELD OF THE INVENTION

The present invention relates to the configuration and the method of an apparatus used to process semiconductor wafers.

### BACKGROUND

Two of the most fundamental processes in integrated circuit (IC) fabrication are chemical vapor deposition (CVD) and etching. CVD processes use vapor precursors for the deposition of thin films on an IC substrate, while etching processes use vapor precursors for etching thin films on an IC substrate. The basic differences between CVD and etching processes are the precursors used and the process conditions applied, since the reaction systems used in both processes are similar. Basically, the reaction system used for both processes consists of a precursor delivery unit, a substrate and an energy source to decompose the precursor vapor to reactive species either to allow a thin film to form on the substrate (CVD process) or to etch an existing thin film on the substrate (etch process). Effective power sources are heat and plasma energy such as radio frequency (RF) power, microwave energy (MW) power, low frequency (10 KHZ-1 MHz) power, and optical energy (e.g. a laser or ultraviolet light) for decomposing the introduced precursors. Also, the substrate could be biased or heated (100° C.-1200° C.), often in the case of CVD processes, to promote the reaction of the decomposed atoms or molecules and to control the physical properties of the deposited films.

The precursor delivery unit is responsible for the introduction of precursor vapor into the reactor. Precursors are chemical compounds that could be brought together in a reactor chamber. The reactive precursors either decompose or react with each other under a catalyst or an energy source. Nonreactive precursors such as helium, nitrogen, and argon are sometimes used to dilute the reactive precursors.

Traditionally, precursors used in semiconductor CVD processes are gaseous. An example of a CVD process to deposit silicon dioxide (SiO₂) is to use gaseous precursors such as silane gas (SiH₄) and oxygen gas (O₂):

SiH₄(gas)+O₂(gas)−(heat→SiO₂(solid)+2H₂(gas)

The basic requirements of a precursor are that the desired product (in this example, SiO₂) is solid, and all other products are gases (in this example, H₂) to be exhausted away. The energy required for the reaction to take place is the thermal energy, about 400-800° C.

To broaden the processes, more and more liquid and solid precursors have been used, especially in the area of metal-organic chemical vapor deposition (MOCVD). To perform this MOCVD task, a liquid precursor is typically turned into vapor, and the vapor is then decomposed and reacts on the substrate. A solid precursor must often be dissolved into a solvent to form a liquid precursor. The liquid precursor then needs to be converted into vapor phase before being introduced into the deposition zone. An example of a CVD process to deposit copper (Cu) is to use liquid precursor Copper HexaFluoroACetylacetone TriMethylVinylSilane (hfac-copper-tmvs, C₅HO₂F₆—Cu—C₅H₁₂Si):

Cu-hfac-tmvs(liquid)−(heat)−Cu-hfac-tmvs(vapor) 2Cu-hfac-tmvs(vapor)−(heat)→Cu(solid)+hfac-Cu-hfac(vapor)+2tmvs(vapor)

Both CVD and etching processes often occur at reduced atmospheric pressure (typically Torr pressure for CVD processes and milliTorr pressure for etching processes) to prevent contamination and impurity incorporation. Typical process reactor then includes a process pump to maintain this reduced atmospheric pressure. These processes also involve hazardous chemicals. Their by-products are also hazardous. The process vapors, composed of the precursors and their by-products, are often toxic chemicals, not only to people, environment, but also to selected metals as well. Therefore all the materials in contact with the precursors and their by-products are often chosen to withstand the possible damage caused by them. For example, etching processes often involve fluorine or chlorine, thus very corrosive. The pump material selected for these applications needs to be treated, such as Teflon coated, to prevent damage. Exhaust flows are also treated to remove all toxic materials before being released to the external atmosphere. Sometimes a trap is used to capture all or part of the toxic materials for re-use or for disposal. Sometimes an abatement unit is used to reduce the toxic components in the exhaust flows before sending them to a treatment unit such as a scrubber.

Since most semiconductor processes occur at reduced atmospheric pressure, often a transfer chamber is needed to prevent exposing the process chamber to atmosphere. FIG. 1 shows a prior art semiconductor processing system having a single transfer housing. The process chamber 1 is always kept under reduced atmospheric pressure with the pumping unit 5. The process evacuation pathway 4 is responsible for evacuating all process vapor in the process volume 2 to atmosphere 7. The process evacuation pathway 4 includes the pumping unit 5 and the process vapor treatment unit 6. The process vapor treatment unit 6 is responsible for treating the process vapor, rendering the process vapor harmless before releasing it into atmosphere 7. The pumping unit 5 and the treatment unit 6 are specially constructed to withstand the damage such as corrosion and etching caused by the process vapor. To start processing, the transfer chamber 13 is vented to atmosphere by a non-reactive, safe gas such as nitrogen or argon (not shown). When the pressure in the transfer chamber 13 reaches atmospheric pressure, the door 12 to the transfer chamber 13 opens and a wafer is introduced into the transfer chamber 13. Door 12 then closes, and the transfer chamber 13 is pumped down to reduced atmospheric pressure through the evacuation pathway 14. The transfer evacuation pathway 14 is responsible for evacuating the transfer volume 11 to atmosphere 16 through the pumping unit 15. Since the transfer volume contains only non-reactive and safe gas, the pumping unit 15 is normally not constructed to withstand the harsh environment as the pumping unit 5 of the process evacuation pathway 4. Also for the same reason, the transfer evacuation pathway 14 normally does not have a toxic treatment unit. Once the transfer chamber 13 achieves similar reduced atmospheric pressure as the process chamber 1, the process door 10 between the transfer chamber 13 and the process chamber 1 opens. Wafer 3 is then transferred into the process chamber 1. Door 10 then closes. The process vapor 8 is then introduced into the process chamber 1 through the process gas inlet 9 for processing the wafer. During the process vapor flow, in order to maintain a desired pressure in the process chamber, the process evacuation pathway 4 is working continuously to evacuate residues, precursor by-products, and nonreactive process precursors generated by the reaction of the process vapor 8 with wafer 3. The process evacuation pathway 4 often includes a pump unit 5 to maintain the reduced atmospheric pressure, an abatement unit (not shown) to reduce the toxic or harmful components of the exhaust flow, a treatment unit 6 to completely neutralize the exhaust flow to render it harmless to the environment before releasing it to the atmosphere. Sometimes the exhaust flow could cause damage to the components of the process evacuation pathway (for example the hfac-Cu-hfac by-product in liquid copper precursor reaction is very corrosive to stainless steel), therefore these components are carefully selected or treated to withstand the damage caused by the exhaust flow, such as Teflon coated to prevent etching from fluorine or chlorine-based precursors. Once the process is completed, the process vapor 8 stops flowing while the process volume 2 continues being pumped out through the process evacuation pathway 4. Then the door 10 to the process chamber 1 opens, and wafer 3 is transferred from the process chamber 1 to the transfer chamber 13. Door 10 closes, and the transfer chamber 13 is vented to atmosphere with non-reactive gas such as nitrogen or argon. Once the transfer chamber 13 reaches atmosphere, door 12 opens and the wafer 3 is taken out of the transfer chamber 13. The processing system is now ready to process the next wafer.

To improve the throughput, a cassette chamber is coupled to the transfer chamber for storing many workpieces. The opening to atmosphere is now at the cassette chamber, and the transfer chamber and the process chamber will not be exposed to atmosphere anymore. FIG. 2 shows a prior art semiconductor processing system having two transfer housings. The first transfer chamber 23 is often called a cassette module (or a cassette chamber), and is used to store the wafers before transferring them to the second transfer chamber 13 and to the process chamber 1. The second transfer chamber 13 is often called a transfer module (or sometimes simply transfer chamber). This system increases the throughput of the processing because the first transfer chamber 23 will need to be vented only once for a cassette of wafers. A typical operation is as followed. Door 22 to the first transfer chamber (or cassette module) 23 opens, and a cassette of wafers is put into the first transfer chamber 23. First transfer chamber 23 is pumped down to reduced atmospheric pressure through the transfer evacuation pathway 24 with pumping unit 25 to atmosphere 26. Door 12 to the second transfer chamber (or transfer module) 13 then opens and one wafer is taken into the second transfer chamber 13. Door 12 closes, door 10 to the process chamber 1 opens and the wafer is taken into the process chamber 1, then door 10 closes and the process starts. After the process ends, the process chamber 1 is pumped down to base pressure (the lowest pressure obtainable by the available pump equipment 5) to evacuate as much as possible the process vapor in the process chamber 1. Then door 10 opens, the wafer returns to the second transfer chamber 13 and door 10 closes. Door 12 opens, the wafer returns to the first transfer chamber 23, and a new wafer is then being transferred into the second transfer chamber 13. The cycle continues until all the wafers in the first transfer chamber are processed. The transfer module could have many process chambers attached to it to allow the wafer to be processed in different process chambers for different processing steps.

The cassette chamber and the transfer chamber are only exposed to air or inert gas since there is no process vapor in these chambers, therefore the components of the cassette evacuation pathway and the transfer evacuation pathway are not rated for toxic or corrosive environment. Furthermore, the transfer module sometimes employs more than one transfer chamber to increase the number of process chambers connecting to it, or to improve the vacuum at an inner stage of the transfer chamber.

The use of liquid precursors in a process can cause problems. Normally with gaseous precursors, it takes only seconds to evacuate the process vapor that consists of process precursors and their by-products because the backflow is small. With liquid precursors, the evacuation process would take many minutes or even hours because the liquid vapor could be adsorbed at the surface of the chamber wall and could only be desorbed very slowly. Therefore with liquid precursors, significant amount of the process precursors and their by-products still exist in the process chamber, hence increasing the amount of process vapor in the backflow. Solutions to reduce the amount of these process vapors in the process chamber such as heating the chamber wall to increase the desorption of precursor vapor, could cause side effects to the processes such as deposition on the chamber wall and chamber conditioning problems.

### SUMMARY

In one aspect, the apparatus includes a process housing defining a process volume and a process evacuation pathway from the process volume to atmosphere. The process housing is for processing a workpiece and the process evacuation pathway is responsible for the evacuation of process vapor in the process volume. The apparatus further includes a plurality of transfer housings coupled linearly to each other and to the process housing with each transfer housing defines a transfer volume and the first transfer housing has at least a transfer opening to atmosphere. The first transfer housing is coupled to the second transfer housing, and so on, and the last transfer housing is coupled to the process housing so that the transfer housings are for transferring the workpiece to and from the process housing. The last transfer housing and the process housing in combination defines a backflow pathway from the process volume to the transfer volume. The apparatus further includes a backflow remover element coupled to the backflow pathway with the backflow remover element being operative in at least one configuration to substantially remove portion of process vapor in the backflow pathway for preventing the process vapor portion from reaching the atmosphere.

Implementations of the above aspect may include one or more of the following. The last transfer housing can include a transfer module for the movement of workpieces to and from the process volume. The backflow removal element can be coupled to the transfer module for removing the process vapor from the backflow pathway in the transfer module to prevent possible cross contamination between process chambers connected to the transfer module. The first transfer housing can include a cassette module for the storage of workpieces to be transferred to and from the process volume. The backflow removal element can be coupled to the cassette module for removing the process vapor from the backflow pathway in the cassette module to prevent possible releasing of the process vapor into atmosphere.

The backflow removal element can include a gas purging unit for purging process vapor in the backflow pathway back toward the process volume, so that the process vapor in the backflow pathway is substantially reduced before escaping the transfer housing and reaching atmosphere. The gas purging unit can employ higher pressure in the transfer volume, thus create a positive flow against the backflow pathway when the process partition door is open. The gas purging unit can employ high flow of purging gas from the transfer volume toward the process volume, thus create a positive flow against the backflow pathway when the process partition door is open. The transfer housing can include a transfer evacuation pathway from the transfer volume to atmosphere so that the transfer evacuation pathway is responsible for the evacuation of transfer vapor in the transfer volume. The backflow remover element can include a gas purging unit for purging the process vapor in the backflow pathway toward the transfer evacuation pathway during the workpiece transfer movements when the process partition door between the process housing and the last transfer housing is open and also during the time when the process partition already closed. The gas purging unit can employ high flow of purging gas from the transfer volume toward the transfer evacuation pathway, thus create a positive flow directing the backflow pathway toward the transfer evacuation pathway. An added benefit is that since the purging can happen anytime, significant reduction of process vapor in the transfer volume due to the backflow pathway is possible. The backflow remover element can include one or more of the following: a pump, a fan, or a venting element connected to the transfer evacuation pathway with the backflow remover element being special constructed to withstand the process vapor. The backflow remover element can vent the process vapor in the backflow pathway toward the transfer evacuation pathway so that the process vapor in the backflow pathway is substantially reduced before reaching atmosphere via the transfer opening. A combination of purging gas and venting through the exhaust pathway can also speed up the removal of process vapor from the backflow pathway.

The backflow remover element can include one or more of the following: a cold trap, a heat trap, a plasma trap, an ionic trap, or an absorption/adsorption surface, so that the backflow remover element traps process vapor from the backflow pathway so that the process vapor in the backflow pathway is substantially reduced from reaching atmosphere via the transfer evacuation pathway. The trap can be connected to the transfer evacuation pathway to trap the process vapor on its way toward the atmosphere. The trap can be connected to the transfer housing to trap the process vapor in the transfer housing. The trap can be a cold trap in the range of about 25° C. to −200° C. and operative in at least one configuration to cause condensation of the process vapor in the transfer evacuation pathway. The transfer housing can be the cold trap itself by having temperature element of about 25° C. to −200° C. and operative in at least one configuration to cause condensation of the process vapor in the transfer housing. The backflow remover element coupled to the transfer evacuation pathway can include a heat trap in the range of about 100 to about 500 degrees Celsius and operative in at least one configuration to cause further reaction of the process vapor in the transfer evacuation pathway. The process vapor in the backflow pathway can include at least one liquid vapor component, or a precursor, precursor by-product or other toxic substance involved in a chemical vapor deposition technique. The apparatus can include a partition between each the housing coupling, so that the process volume and each the transfer volume are isolated when the partition is close.

In a second aspect, a method is disclosed to remove the process vapor from a backflow pathway from a process chamber to a transfer chamber. The process vapor is originated from a processing chamber with the process chamber having a separate evacuation pathway for removing the process vapor. The method includes activating a backflow remover element to substantially remove process vapor in the backflow pathway and to prevent process vapor from reaching atmosphere.

Implementations of the second aspect may include one or more of the following. The activating a backflow removal element can include purging the backflow pathway, or purging and pumping cycle to substantially remove process vapor in the backflow pathway, or trapping the precursor vapor in the backflow pathway. The purging operation can push back the process vapor toward the process volume, or push the process vapor toward the transfer evacuation pathway. The trap can be coupled to the transfer evacuation pathway, or coupled to the transfer housing itself. The process vapor in the backflow pathway can include at least one liquid vapor component. These operations can be inserted anywhere in the sequence of workpiece movements from the cassette module to the transfer module to the process chamber to monitor and reduce the precursor vapor in the backflow pathway. The backflow removal steps can start at the beginning of the process sequence and only stops when all the workpieces are complete processed. The backflow removal steps can start only before or after the process door open when there is significant backflow.

In yet another aspect, an apparatus for semiconductor processing includes a process chamber having a process evacuation pathway from the process volume to atmosphere; a transfer module to transfer a workpiece to and from the process chamber, the transfer module and process chamber in combination defining a backflow pathway; and a backflow remover element coupled to the backflow pathway, the backflow remover element removing a portion of process vapor in the backflow pathway.

Advantages of the invention may include one or more of the following. The apparatus addresses a need for advanced processing techniques and increasing environmental concerns because measurable amount of the process vapor could still exist in the process chamber, especially when using liquid precursors, and the presence of this process vapor in the transfer chamber or cassette chamber could cause significant damage, either to the operator, the environment, or to the equipment. The apparatus avoids releasing harmful vapors to the environment through the cassette chamber door when workpieces are taken into and out of the cassette chamber, or through the cassette or transfer evacuation pathway. By avoiding or minimizing the release of these harmful vapors, the apparatus minimizes potential of damage to the components in these evacuation pathways since these components, such as vacuum pumps, are not rated for toxic or corrosive substances.

### INCORPORATED DISCLOSURES

The invention described herein can be used in conjunction with invention described in the following applications:

Ser. No. 09/589,636, in the name of Tue Nguyen, titled “High Pressure Chemical Vapor Trapping System”, filing date Jun. 7, 2000, assigned to the same assignee, attorney docket number SIM013.

Ser. No. 09/589,633, in the name of Tue Nguyen and Craig Alan Bercaw, titled “Visual Indicator Cold Trapping System”, filing date Jun. 7, 2000, assigned to the same assignee, attorney docket number SIM014.

Ser. No. ______, in the name of Tue Nguyen, titled “Apparatus and method for monitoring backflow vapors”, filing date ______, assigned to the same assignee, attorney docket number SIM041.

### BRIEF DESCRIPTION OF THE DRAWINGS

FIG. 1 shows a prior art semiconductor processing system having a single transfer housing.

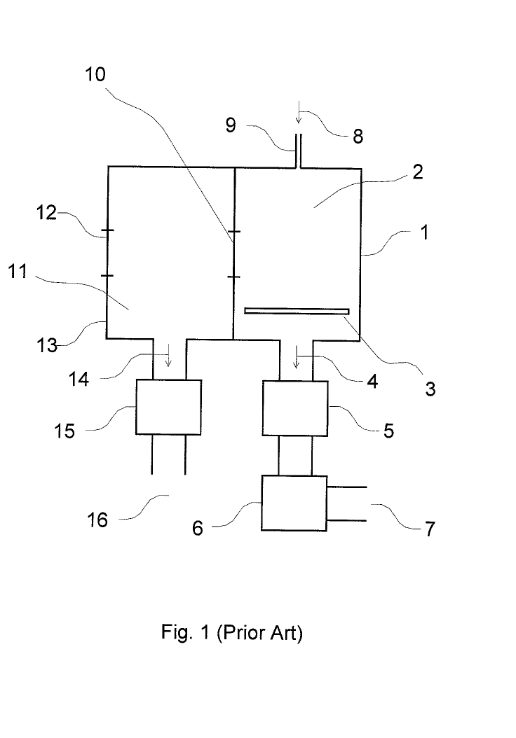

FIG. 2 shows another prior art semiconductor processing system having two transfer housings.

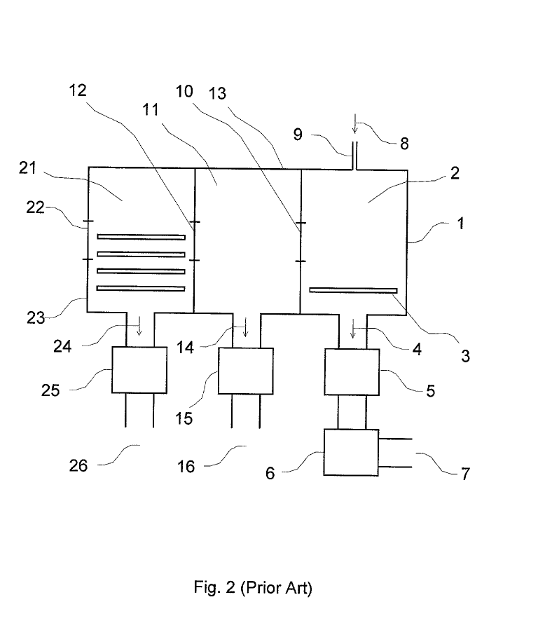

FIG. 3 shows the present invention apparatus on a single transfer housing system.

FIG. 4 shows the present invention apparatus on two transfer housing system.

FIG. 5 shows the workpiece transfer movements and possible backflow removal steps in a single transfer housing system.

FIG. 6 shows the workpiece transfer movements and possible backflow removal steps in a two transfer housing system.

### DETAILED DESCRIPTION

An apparatus and method for removing backflow vapors in workpiece processing is disclosed. The apparatus addresses a need for liquid precursors and also could be useful with gaseous precursors by removing the backflow of the process vapor from the process chamber. With gaseous precursors, it takes only seconds to evacuate the process vapor, consisting of process precursors and their by-products, therefore the backflow is small. With liquid precursors, the evacuation process would take many minutes or even hours because the liquid vapor could be adsorbed at the surface of the chamber wall and only very slowly desorbed. Therefore with liquid precursors, significant amount of the process precursors and their by-products still exist in the process chamber, increasing the amount of process vapor in the backflow. Solutions to reduce the amount of process vapor in the process chamber such as heating the chamber wall to increase the desorption of precursor vapor, could cause side effects to the processes such as deposition on the chamber wall, lacking of chamber conditioning.

Therefore, in many instances, the backflow of the process vapor toward the transfer chamber and the cassette chamber could cause significant damage. Harmful vapor could be released to the environment when the workpieces are taken in and out of the cassette chamber, or through the cassette or transfer evacuation pathway since there is no toxic remover in these pathways because of the assumption that there would be no toxic materials in these pathways. There could be damages to the components in these evacuation pathways since these components, such as vacuum pumps, are not rated for toxic or corrosive substances.

The apparatus according to the present invention includes a backflow removal element to remove the precursors and their by-products. The backflow pathway carries the process vapor, composed of precursor vapors and their by-products, from a process housing to a transfer housing directly coupled to the process housing. The process housing already has a process evacuation pathway to evacuate all process vapor in the process volume, however, measurable amount of process vapor could still backflow toward the transfer chamber. The process evacuation pathway is normally well designed to handle the toxicity and corrosiveness of the precursors and their by-products. To move a workpiece in and out of the process housing, a transfer housing is coupled to the process housing. Normally a process partition door is present between the process housing and the transfer housing. This partition door is open during the transfer of the workpiece and close during the processing of workpiece to prevent precursors and their by-products from escaping the process volume. However, some precursors and by-products might still be present after the processing, especially with liquid precursor vapors, and thus can escape to the transfer housing during the transfer of the workpiece. This is the backflow of the precursor and their by-products.

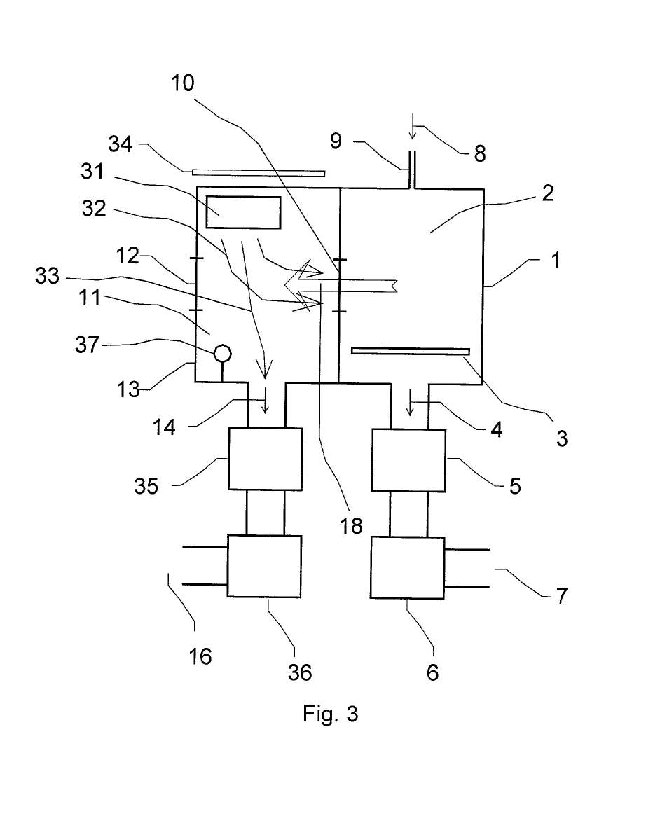

FIG. 3 shows the apparatus on a single transfer housing system. The backflow pathway 18 carrying significant process vapor from the process volume 2 to the transfer volume 11 when the partition door 10 is open. For gaseous precursors, the backflow is small after a few second pumping through the evacuation pathway 4 of the process volume 2 before opening the partition door 10. However, for liquid precursor vapor, the backflow 18 is significant. Also the presence of liquid process vapor in the process volume 2 is sometimes needed for conditioning the process chamber 1, thus increasing the backflow 18 significantly. The presence of process vapor through the backflow 18 causes significant risk, both to the equipment and the operators. The pumping unit 15 could fail prematurely because of the process vapor. The process vapor could be released into the face of the operator when the transfer chamber door 12 is open. The process vapor could damage the environment 16 without a treatment unit at the transfer evacuation pathway 14. The apparatus includes various backflow removal elements to remove the process vapor from the transfer housing. These backflow remover elements can be used together to improve the removal capability. A backflow remover element 31 is a gas purging unit. A gas purging unit could include a non-reactive or inert gas inlet to purge the precursor vapor backflow. The gas purging unit 31 could raise the pressure in the transfer volume 11, or could produce a high flow 32 to push the backflow back toward the process chamber 1 when the process partition door 10 is open. This method is not very effective because no matter how high the pressure or the flow, there is always some backstream flow of precursor vapor. Other purging technique occurs after the partition door 10 is close. The gas purging unit 31 produces the gas flow 33 to push the backflow toward the transfer evacuation pathway 14. Together with the pumping unit 35, this is an effective way to prevent the backflow from reaching the door 12. The pumping unit 35 needs to be specially constructed to prevent damage due to the process vapor flow. Also since the transfer evacuation pathway 14 now carries the process vapor from the backflow pathway, another backflow remover element is needed to remove the process gas from the transfer evacuation pathway 14. A backflow remover element 36 is a process vapor trap to trap all process vapor. The preferred embodiment is a cold trap, in the range of 25° C. to −200° C., to condense all process vapor and capture to prevent from releasing to atmosphere 16. Sometimes a heat trap is used in conjunction with a cold trap. The heat trap further the reactions, so that the process vapor now will be less precursor vapor and more precursor by-products. The temperature of the heat trap is typically between 100° C. and 500° C. Another backflow remover element is the cold trap 34. The transfer chamber 13 is cooled down to the trap temperature, thus itself becoming a huge cold trap. The drawback of this cold trap 34 is that the process vapor is still captured in the transfer volume 11, thus when door 12 is open, the operator might still be exposed to some process vapor releasing from the trap.

There could be a plurality of transfer housings. These transfer housing are coupled linearly to each other and to the process housing. The first housing coupled to the second housing, and so on, and the last housing coupled to the process housing. The first transfer housing has an opening to atmosphere to transfer the workpiece in and out of the transfer housing. The transfer housing are coupled to each other so that the workpiece can transfer from the first transfer housing to the last transfer housing. These transfer housings further have partition doors between each housing to isolate the transfer housing. Similar to the process partition door, these partition doors are open only during the transfer of the workpiece through the transfer housings that are connected, and close all other times. The last transfer housing is coupled to the process housing through the process partition door. The precursors and their by-products escape the process housing through the backflow pathway, and could travel through all the transfer housings. The precursors and their by-products could leak out to atmosphere at the first transfer housing when the partition door is open to transfer the workpiece, or could leak out through any of the transfer housings. The first transfer housing could be a cassette module for the storage of the workpieces to be transferred to and from the process housing. The last transfer housing could be a transfer module for the transfer of the workpieces to and from the process housing.

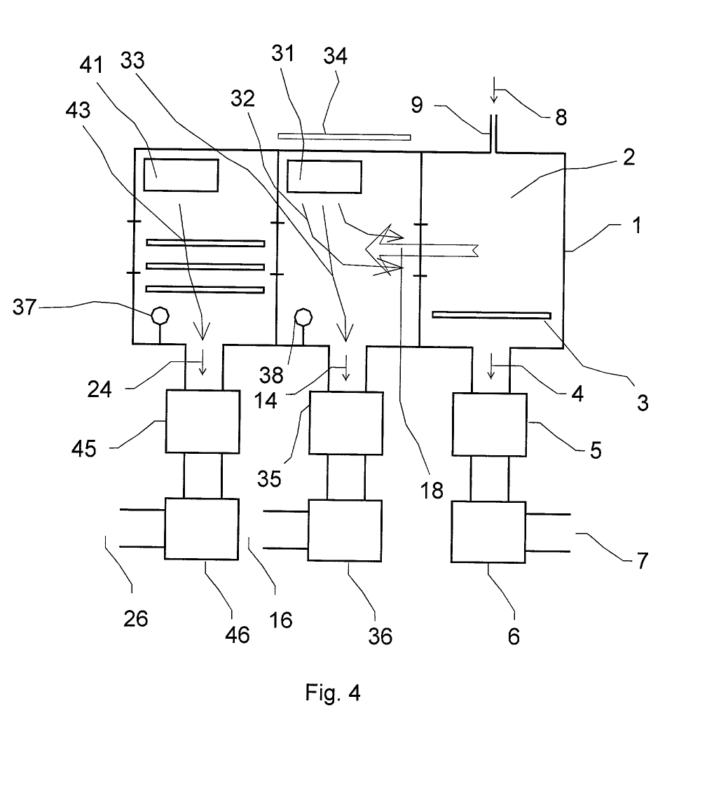

FIG. 4 shows the apparatus on two transfer housing system. In this configuration, the drawback of the cold trap 34 disappears because the process vapor is trapped in the second transfer chamber and with the door between the first and second transfer chamber close, no process vapor can escape. The apparatus includes the backflow removal elements in the first and second transfer chambers. Similar backflow remover elements can be put on the first transfer chamber as on the second transfer chamber as in FIG. 3, such as gas purging unit 41, process vapor trap 46, specially constructed pumping unit 45. We have observed damage to a regularly constructed pumping unit 45 connected to the first transfer chamber when running liquid copper precursor (copper-hfac-tmvs). The copper precursor and its by-products escape the process chamber through the backflow pathway, further escape the second transfer chamber 13 because the doors 12 and 10 are open at the same time for improving throughput, and being pumped out through the first transfer evacuation pathway 24, thus damage the pumping unit 45.

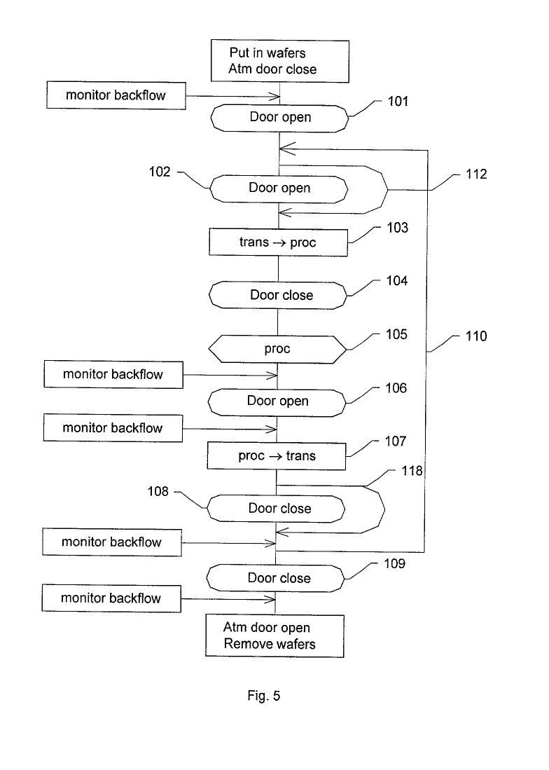

FIG. 5 shows the workpiece transfer movements and possible backflow removal steps in a single transfer housing system. The operator opens the door to the atmosphere (atm door) and put the workpieces in the transfer chamber. The atm door closes and the transfer chamber pumps down to reduced atmospheric pressure. To start the process sequence, the door between the process and the transfer chamber opens (step 101). Step 102 (opens this door) or step 112 (skips opening the door) is for looping purpose. Then the workpiece is transferred from the transfer chamber to the process chamber (step 103). Then the door between the process and the transfer chamber closes (step 104). Process starts (step 105). Then the door between the process and the transfer chamber opens (step 106). Then the workpiece is transferred from the process chamber to the transfer chamber (step 107). Then the door between the process and the transfer chamber closes (step 108). The sequence continues back to step 102 again for the next workpiece (step 110). Steps 108 and 102 could be skipped (steps 118 and 112) and the door just remains open during the time when an old workpiece is transferred out of and a new workpiece into the process chamber. After the last workpiece, the door closes (step 109). The operator then could vent the transfer chamber to atmospheric pressure, open the atm door to the atmosphere, and remove the workpieces. The backflow removal step could be inserted anywhere in this sequence. For a most complete backflow removal step, the backflow removal starts when the process sequence begins (before step 101), and stops when the process sequence ends. A shorter backflow removal step starts before the process partition door opens (before step 106) to remove the backflow and stops after the door closes (after step 104). Another shorter backflow removal step starts after the process partition door opens (after step 106) and stops before the door closes (before step 104). The shortest backflow removal step runs only during step 110.

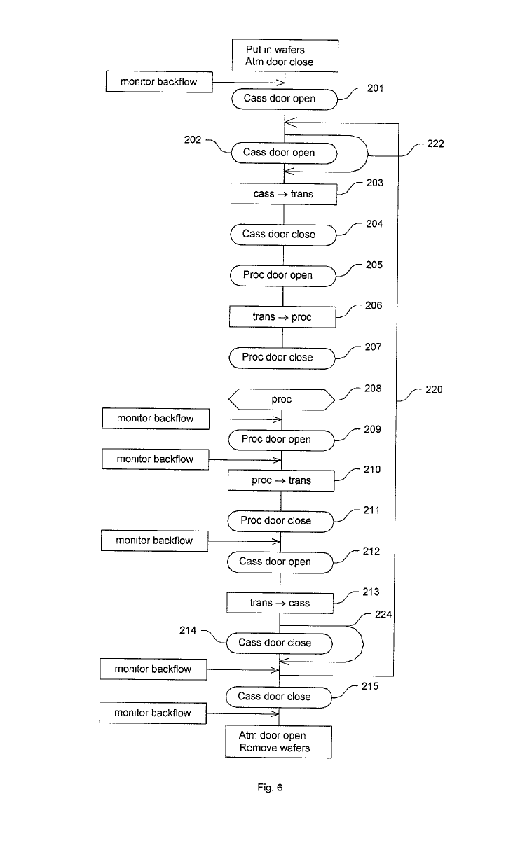

FIG. 6 shows the workpiece transfer movements and possible backflow removal steps in a two transfer housings system having one transfer module and one cassette module. The operator opens the door to the atmosphere (atm door) and put the workpieces in the cassette chamber. The atm door closes and the cassette chamber pumps down to reduced atmospheric pressure. When the process sequence starts, the cassette door opens (step 201), and a workpiece is transferred from the cassette to the transfer module (step 203). The cassette door closes (step 204). The process door opens (step 205), and the workpiece is transferred from the transfer module to the process chamber (step 206). The process door closes (step 207) and process starts (step 208). After the workpiece is finished processing, the process door opens (step 209), and the workpiece is transferred from the process chamber back to the transfer module (step 210). The process door closes (step 211), and the cassette door opens (step 212). The workpiece is now transferred from the transfer module to the cassette module (step 213). The cassette door closes (step 214), and the sequence continues for the next workpiece (step 220). Often for a faster movement, the cassette door remains open during the time when a processed workpiece comes in and a new workpiece goes out (steps 202 and 214 become steps 222 and 224). After all the workpieces are processed, the cassette door closes (step 215) and the cassette of workpieces is ready to be taken out. The operator then could vent the cassette chamber to atmospheric pressure, open the atm door to the atmosphere, and remove the workpieces. Similar to the sequence with one transfer chamber, the backflow removal step can be inserted anywhere in the sequence. For a complete backflow removal, the backflow removal step starts when the process sequence begins (before step 201) and stops when the process sequence ends (after step 215). The backflow removal step could start after the process partition door closes (after step 212), and stop before the process partition door opens (before step 205), to prevent the backflow removal from affecting the process chamber.

Although a preferred embodiment of practicing the method of the invention has been disclosed, it will be appreciated that further modifications and variations thereto may be made while keeping within the scope of the invention as defined in the appended claims.

What is claimed is:

1. An apparatus for removing backflow vapors in workpiece processing, comprising:
a process housing defining a process volume, the process housing having a process evacuation pathway from the process volume to atmosphere;
one or more transfer housings to transfer a workpiece to and from the process housing, each transfer housing defining a transfer volume, the one or more transfer housings and the process housing in combination defining a backflow pathway from the process volume to the transfer volume; and
a backflow remover element coupled to the backflow pathway, the backflow remover element being operative to substantially remove a portion of process vapor in the backflow pathway to prevent the process vapor portion from reaching the atmosphere.

2. Apparatus as in claim 1, wherein one of the transfer housings includes a transfer module for the movement of workpieces to and from the process volume.

3. Apparatus as in claim 1, wherein one of the transfer housings includes a cassette module for the storage of workpieces to be transferred to and from the process volume.

4. Apparatus as in claim 1, wherein the backflow remover element includes a gas purging unit to purge process vapor in the backflow pathway toward the process volume.

5. Apparatus as in claim 1, wherein one of the transfer housings further includes a transfer evacuation pathway from the transfer volume to atmosphere, whereby the transfer evacuation pathway evacuates transfer vapor in the transfer volume.

6. Apparatus as in claim 5, wherein the backflow remover element includes a gas purging unit for purging process vapor in the backflow pathway toward the transfer evacuation pathway.

7. Apparatus as in claim 5, wherein the backflow remover element includes one or more of the following: a pump, a fan, or a venting element, the backflow remover element coupled to the transfer evacuation pathway, whereby the backflow remover element vents process vapor in the backflow pathway toward the transfer evacuation pathway.

8. Apparatus as in claim 5, wherein the backflow remover element includes one or more of the following: a cold trap, a heat trap, a plasma trap, an ionic trap, or an absorption/adsorption surface, the backflow remover element coupled to the transfer evacuation pathway, whereby the backflow remover element traps process vapor from the backflow pathway.

9. Apparatus as in claim 8, wherein the backflow remover element includes a cold trap in the range of about 25 to about −200 degrees Celsius and operative to cause condensation of the process vapor in the transfer evacuation pathway.

10. Apparatus as in claim 8, wherein the backflow remover element includes a heat trap in the range of about 100 to about 500 degrees Celsius and operative to cause a reaction of the process vapor in the transfer evacuation pathway.

11. Apparatus as in claim 1, wherein the backflow remover element includes one or more of the following: a cold trap, a heat trap, a plasma trap, an ionic trap, or an absorption/adsorption surface, the backflow remover element coupled to the transfer housings, whereby the backflow remover element traps process vapor from the backflow pathway.

12. Apparatus as in claim 11, wherein the backflow remover element includes a cold trap in the range of about 25 to about -200 degrees Celsius and operative in at least one configuration to cause condensation of the process vapor in the transfer housings.

13. Apparatus as in claim 1, wherein the process vapor in the backflow pathway includes at least one liquid vapor component.

14. Apparatus as in claim 1, wherein the process vapor in the backflow pathway includes at least one precursor, precursor by-product or other toxic substance involved in chemical vapor deposition.

15. Apparatus as in claim 1, further including a partition between each the housing coupling, whereby the process volume and each the transfer volume are isolated when the partition is closed.

16. A method to reduce process vapor from a backflow pathway from a process chamber to a transfer chamber, the process vapor being originated from a processing chamber, the method comprising:
a) diverting the process vapor from the process chamber through a separate evacuation pathway; and
b) removing process vapor in the backflow pathway and preventing process vapor from reaching atmosphere.

17. A method as in claim 16 wherein the removing process vapor includes purging the backflow pathway.

18. A method as in claim 16 wherein the removing process vapor includes purging and pumping gas to substantially remove process vapor in the backflow pathway.

19. A method as in claim 16 wherein the removing process vapor includes trapping the precursor vapor in the backflow pathway.

20. A method as in claim 16 wherein the removing process vapor in the backflow pathway includes providing at least one liquid vapor component.

21. A method as in claim 16, further comprising moving a workpiece while removing the process vapor in the backflow pathway.

22. An apparatus for semiconductor processing, comprising:
a process chamber having a process evacuation pathway from the process volume to atmosphere;
a transfer module to transfer a workpiece to and from the process chamber, the transfer module and process chamber in combination defining a backflow pathway; and
a backflow remover element coupled to the backflow pathway, the backflow remover element removing a portion of process vapor in the backflow pathway.

23. Apparatus as in claim 22, further comprising a second backflow remover element coupled to the chamber.

24. Apparatus as in claim 22, wherein the transfer module is housed in a housing.

25. Apparatus as in claim 22, wherein the transfer module includes a cassette module for the storage of a workpiece.

26. Apparatus as in claim 22, wherein the backflow remover element includes a gas purging unit to purge process vapor in the backflow pathway.

27. Apparatus as in claim 22, wherein the transfer module further includes a transfer evacuation pathway to atmosphere, whereby the transfer evacuation pathway evacuates transfer vapor in a transfer volume.

28. Apparatus as in claim 27, wherein the backflow remover element includes a gas purging unit for purging process vapor in the backflow pathway toward the transfer evacuation pathway.

29. Apparatus as in claim 27, wherein the backflow remover element includes one or more of the following: a pump, a fan, or a venting element, the backflow remover element coupled to the transfer evacuation pathway, whereby the backflow remover element vents process vapor in the backflow pathway toward the transfer evacuation pathway.

30. Apparatus as in claim 27, wherein the backflow remover element includes one or more of the following: a cold trap, a heat trap, a plasma trap, an ionic trap, or an absorption/adsorption surface, the backflow remover element coupled to the transfer evacuation pathway, whereby the backflow remover element traps process vapor from the backflow pathway.

31. Apparatus as in claim 27, wherein the backflow remover element includes a cold trap in the range of about 25 to about -200 degrees Celsius and operative to cause condensation of the process vapor in the transfer evacuation pathway.

32. Apparatus as in claim 27, wherein the backflow remover element includes a heat trap in the range of about 100 to about 500 degrees Celsius and operative to cause a reaction of the process vapor in the transfer evacuation pathway.

33. Apparatus as in claim 27, wherein the backflow remover element includes one or more of the following: a cold trap, a heat trap, a plasma trap, an ionic trap, or an absorption/adsorption surface, the backflow remover element coupled to the transfer housings, whereby the backflow remover element traps process vapor from the backflow pathway.

34. Apparatus as in claim 27, wherein the backflow remover element includes a cold trap in the range of about 25 to about -200 degrees Celsius and operative in at least one configuration to cause condensation of the process vapor in the transfer housings.

35. Apparatus as in claim 22, wherein the process vapor in the backflow pathway includes at least one liquid vapor component.

36. Apparatus as in claim 22, wherein the process vapor in the backflow pathway includes at least one precursor, precursor by-product or other toxic substance involved in a chemical vapor deposition.

37. Apparatus as in claim 22, further including a partition between each the housing coupling, whereby the process volume and each the transfer volume are isolated when the partition is closed.
